(19) United States
(12) Patent Application Publication
(10) Pub. No.: US 2011/0254417 A1
(43) Pub. Date: Oct. 20, 2011

(54) HINGE ASSEMBLY FOR FOLDABLE ELECTRONIC DEVICE

(75) Inventors: CHAO DUAN, Shenzhen City (CN); CHIA-HUA CHEN, Shindian (TW)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 12/889,600

(22) Filed: Sep. 24, 2010

(30) Foreign Application Priority Data
Apr. 19, 2010 (CN) 201010150203.0

(51) Int. Cl. H05K 5/03; E05F 1/12

(52) U.S. Cl. 312/319.2; 16/303

(57) ABSTRACT

A hinge assembly includes a shaft, a cam, a follower, and a resilient member. The follower is disposed on the shaft, one end of the follower having a first cam surface, the first cam surface forming a first sub-cam portion. The cam is positioned on the shaft and adjacent to the follower, the cam having a second cam surface, the second cam surface engaging with the first cam surface. The second cam surface forms a second sub-cam portion, and the first sub-cam portion engages with the second sub-cam portion. The resilient member is placed around the shaft forcing the first cam surface against the second cam surface. After the first sub-cam portion slides and rotates relative to the second sub-cam portion, the first cam surface slides and rotates relative to the second cam surface.

### BACKGROUND

1. Technical Field

The present disclosure generally relates to hinge assemblies and, more particularly, to a hinge assembly for hinging together housings of foldable electronic devices such as mobile telephones, electronic notebooks, and so on.

2. Description of Related Art

Generally, foldable electronic devices have a main body and a cover. Various types of hinge assemblies are used to join the main body and the cover of the foldable electronic device, so that the cover can unfold from and fold on the main body.

A conventional hinge assembly includes a shaft, a cam with peaks, a follower with peaks, and a spring. The cam, the follower, and the spring are mounted on the shaft. The follower engages with the cam. Most conventional hinge assemblies need the peaks of the cam to abut against neighboring positions of the peaks of the follower for providing a large circumferential component of force therebetween to make the cam and the follower rotate relative to each other. A manual opening angle of the hinge assembly, which is the angle the user must manually open the before the phone automatically opens to its full open position, corresponds to a route from the neighboring position to over the peak of the follower. As the distance between the neighboring position and the peak becomes smaller, the circumferential component of force therebetween becomes larger. To provide a larger circumferential component of force therebetween, the manual opening angle has to be very small thus limiting the foldable electronic device to a small manual opening angle.

Therefore, there is room for improvement within the art.

### BRIEF DESCRIPTION OF THE DRAWINGS

Many aspects of the present hinge assembly for foldable electronic device can be better understood with reference to the following drawings. The components in the drawings are not necessarily drawn to scale, the emphasis instead being placed upon clearly illustrating the principles of the present hinge assembly for foldable electronic device. Moreover, in the drawings, like reference numerals designate corresponding parts throughout the several views.

FIG. 1 is an exploded, isometric view of a hinge assembly, according to an exemplary embodiment.

FIG. 2 is an enlarged, isometric view of the follower of the hinge assembly shown in FIG. 1.

FIG. 3 is an enlarged, isometric view of the follower from another aspect.

FIG. 4 is an enlarged, isometric view of the cam of the hinge assembly shown in FIG. 1.

FIG. 5 is an enlarged, isometric view of the cam from another aspect.

FIG. 6 is an assembled, isometric view of the hinge assembly shown in FIG. 1.

FIG. 7 is an isometric view of a foldable electronic device with the hinge assembly shown in FIG. 1.

FIG. 8 is an initial state view of the hinge assembly showing a first sub-cam portion abutting against a second sub-cam portion.

### DETAILED DESCRIPTION

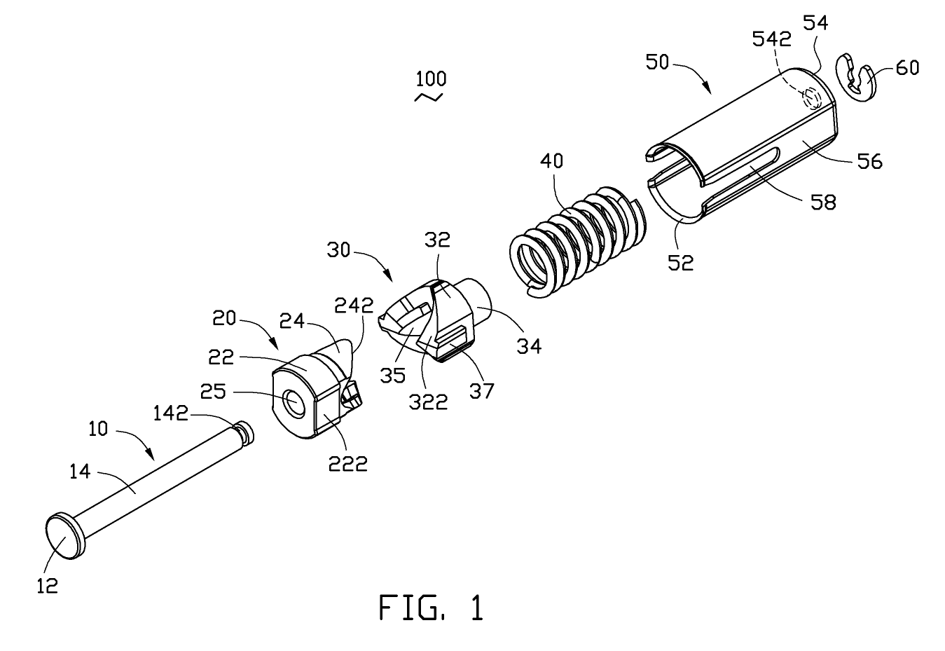

FIG. 1 shows a hinge assembly 100 according to an exemplary embodiment of the present hinge system. The hinge assembly 100 includes a main shaft 10, a follower 20, a cam 30, a resilient member 40, a sleeve 50, and a tooth-lock washer 60.

The main shaft 10 coaxially includes a head portion 12 and a shaft portion 14. The shaft portion 14 extends from one end of the head portion 12 and has a smaller diameter than the diameter of the head portion 12. A free end of the shaft portion 14 defines a ring groove 142.

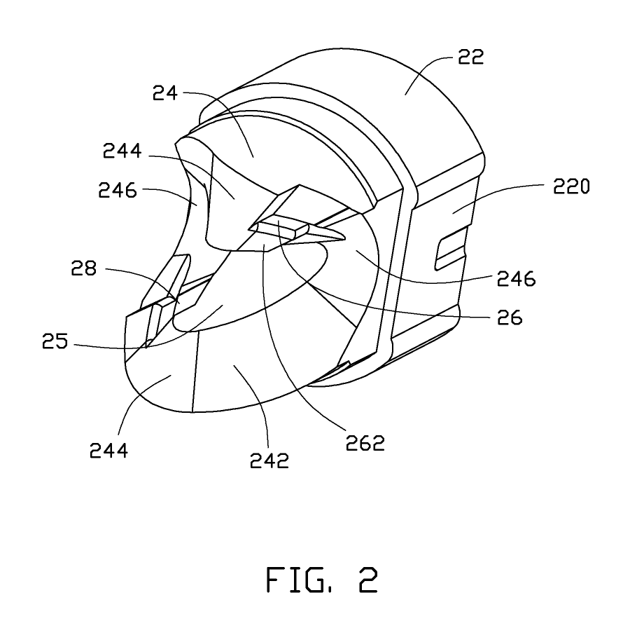

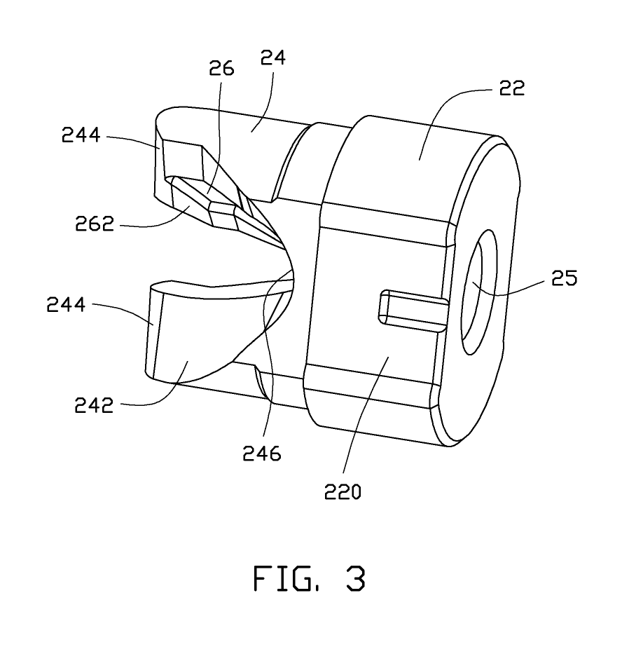

Referring to FIGS. 2 and 3, the follower 20 includes a fixing portion 22 and a cam portion 24 formed in any manner not allowing them to rotate relative to one another. For example, they can be integrally formed together. The fixing portion 22 forms at least one, and in this exemplary embodiment, two symmetric planar surfaces 220. The follower 20 defines a hole 25. The shaft portion 14 may be received in the hole 25, and the head portion 12 may abut against the fixing portion 22. The cam portion 24 includes at least one, and in this exemplary embodiment two symmetric first cam surfaces 242. Each first cam surface 242 includes a peak 244 and a valley 246. A first sub-cam portion 26 projects from one of the first cam surfaces 242 between one peak 244 and one adjacent valley 246, and a first groove 28 is defined in the other of the first cam surfaces 242 between another peak 244 and another valley 246. The first sub-cam portion 26 is positioned at an inside of the first cam surface 242, and includes a first sub-cam surface 262 made of a plurality of sub-surfaces. The first groove 28 is defined inside of the other first cam surface 242, and communicates with the hole 25.

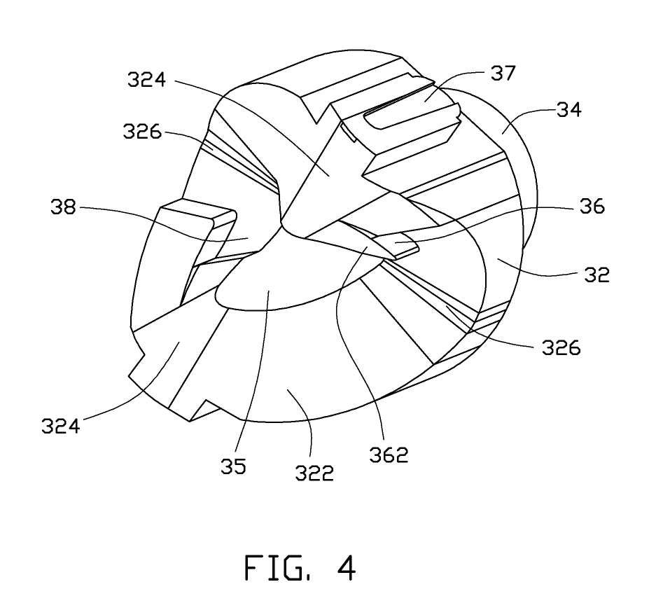

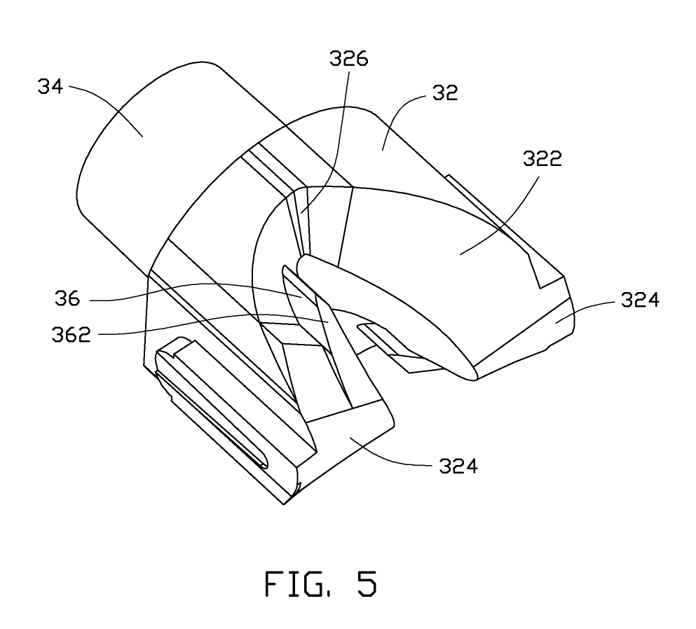

Referring to FIGS. 4 and 5, the cam 30 includes a latching cam portion 32 and an extending portion 34 extending from the latching cam portion 32. A diameter of the extending portion 34 is less than the diameter of the latching cam portion 32. At least one, and in this exemplary embodiment two projections 37 are symmetrically formed on an outer periphery of the latching cam portion 32. A longitudinal passage 35 defined in the cam 30 receives the shaft portion 14. The latching cam portion 32 includes second cam surfaces 322 for engaging with the first cam surfaces 242 of the follower 20. There is one second cam surface 322 for each first cam surface 242. Each second cam surface 322 includes a peak 324 and a valley 326. A second sub-cam portion 36 projects from one of the second cam surfaces 322 between one peak 324 and one valley 326, and a second groove 38 is defined in the other of the second cam surfaces 322 between another peak 324 and valley 326. The second sub-cam portion 36 is positioned inside of the second cam surface 322, and includes a second sub-cam surface 362 made of a plurality of sub-surfaces. The second groove 38 is defined inside of the other second cam surface 322, and communicates with the passage 35. The first sub-cam portion 26 can engage with the second sub-cam portion 36 to allow the cam 30 to rotate relative to the follower 20. The first, second grooves 28, 38 provide spaces for receiving the first, second sub-cam portions 26, 36.

The resilient member 40 can be spiral-shaped (e.g. a coil spring). An inner diameter of the resilient member 40 is slightly larger than an outer diameter of the shaft portion 14 so the resilient member 40 can be placed around the main shaft 10.

The sleeve 50 is substantially a hollow cylinder. The sleeve 50 includes an open end 52 and a partially-closed end 54. The partially-closed end 54 has a central hole 542. The sleeve 50 forms at least one flat surface portion 56 along an outer peripheral wall thereof. The number of flat surface portions 46 corresponds to the number of planar surfaces 220. The flat surface portions 56 extend from the partially-closed end 54. A guide slot 58 is defined in each flat surface portion 56. The projections 37 of the cam 30 are slidably engaged in the guide slots 58. Therefore, the number of guide slots 58 should correspond to the number of projections 38.

The washer 60 is made of a strong material, such as metal. In the exemplary embodiment, the washer 60 is substantially C-shaped and is clasped in the ring groove 142, thereby mating with the main shaft 10.

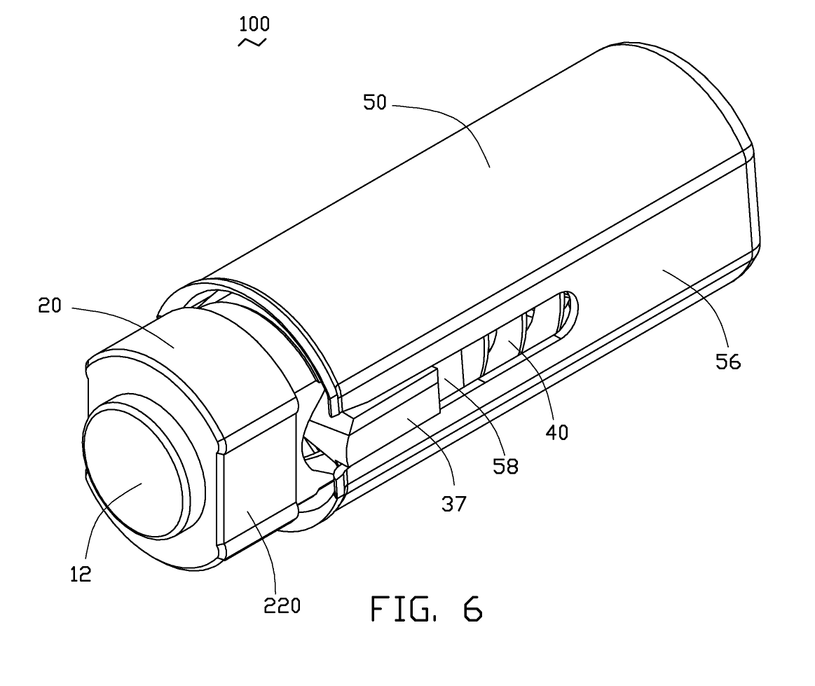

Referring to FIG. 6, in assembly, the follower 20, the cam 30, and the resilient member 40 are mounted on the shaft 10. The second cam surface 322 of the cam 30 engages with the first cam surface 242 of the follower 20. The first sub-cam portion 26 engages in the second groove 38, and the second sub-cam portion 36 engages in the first groove 28. Each projection 37 of the cam 30 is received in a corresponding guiding slot 58. One end of the resilient member 40 is placed around the extending portion 34, and the other end of the resilient member 40 abuts against the partially-closed end 54. One free end of the main shaft 10 passes through the central hole 542, and the washer 60 is mounted in the ring groove 142. Thus, the hinge assembly 100 is integrated into a complete unit.

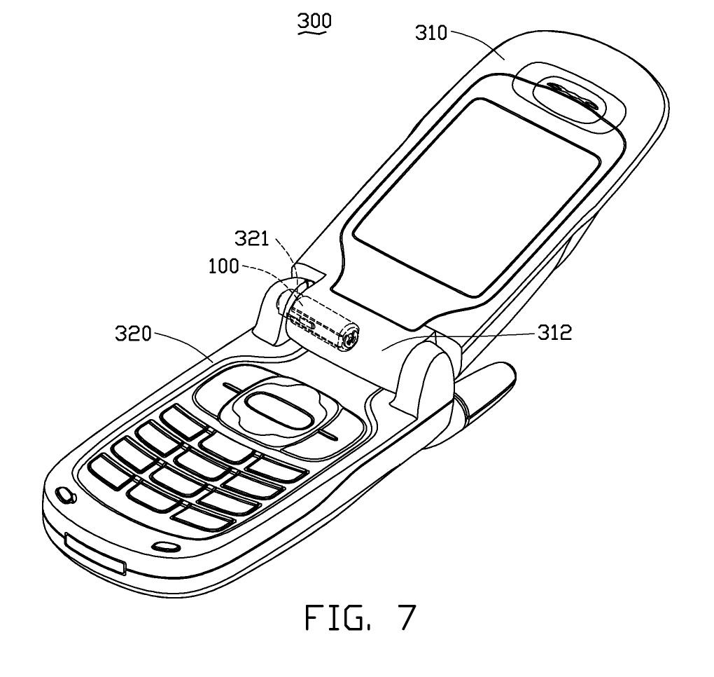

Referring to FIG. 7, the hinge assembly 100, in the exemplary embodiment, interconnects a main body 320 and a cover 310 of a foldable electronic device 300. The cover 310 has a hinge barrel 312 formed at one end. The main body 320 defines a mounting hole 321 in one end. When mounting the hinge assembly 100 to the foldable electronic device 300, the hinge assembly 100 is partially received in the hinge barrel 312. The head portion 12 is pushed to move towards the washer 60, hence the follower 20 moves and compresses the resilient member 40. When the head portion 12 and the follower 20 are moved further into the sleeve 50 and the hinge barrel 312 and face the mounting hole 352, the head portion 12, and the follower 20 are released and automatically move into the mounting hole 321 due to the decompression of the resilient member 40. The planar surfaces 220 of the fixing portion 22 engage the mounting hole 321 of the main body 320, and thus the sleeve 50 non-rotatably engages with the cover 310.

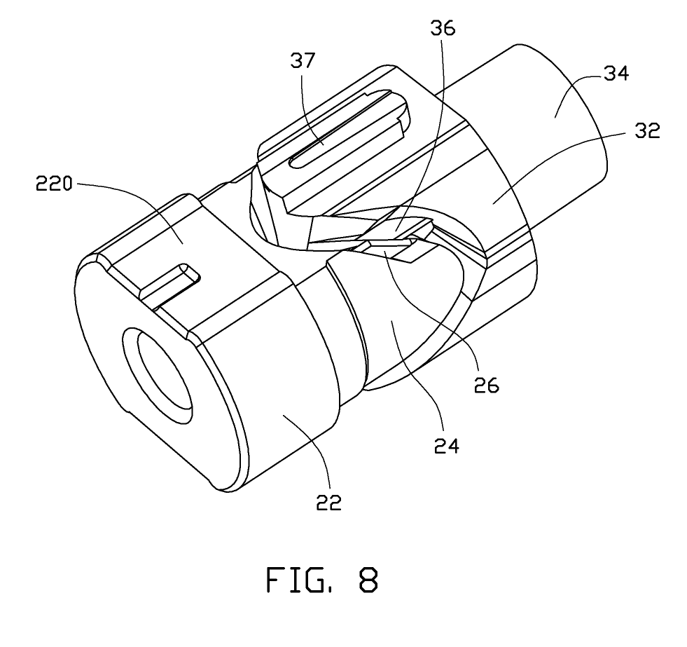

When the cover 310 is closed relative to the main body 320, referring to FIG. 8, The first sub-cam portion 26 engages with the second sub-cam portion 36. The part of the first cam surface 242 at one side of the first groove 28 engages with the second cam surface 322 with the second groove 38. The resilient member 40 is compressed to enable the cover 310 and the main body 320 to be in an original closed, stable state.

To open the foldable electronic device 300, the cover 310 is manually rotated away from the main body 320, hence the sleeve 50 and the cam 30 rotate relative to the follower 20. The first sub-cam surface 262 moves relative to the second sub-cam surface 362 until the first sub-cam portion 26 moves out from the second sub-cam portion 36. The peaks 324 of the second cam surface 322 will slide along the first cam surface 242, and the resilient member 40 is compressed. When the cover 310 is opened to a predetermined angle, the peaks 324 slide over the peaks 244 of the first cam surfaces 242. At the same time, the resilient member 40 is almost completely compressed. Then, when the cover 310 is released, the cam 30 automatically rotates relative to the follower 20 due to the expansion of the resilient member 40 as the peaks 324 slide down along the first cam surface 242. When the cover 310 is opened to about 165 degrees relative to the main body 320, the peaks 324 will have slid to the valley 326. The first sub-cam portion 26 engages in the second groove 38, and the second sub-cam portion 36 engages in the first groove 28. Thus, the cover 310 is automatically rotated to a fully and stable open state, The process of closing the cover 310 is reverse to the process of opening the cover 310.

Since the first sub-cam portion 26 engages with the second sub-cam portion 36 in an initial close state, it can secure a small axial clearance between the cam 30 and the follower 20 to reduce the deformation of the cam 30 and the follower 20. In addition, the first sub-cam portion 26 can firstly rotate relative to the second sub-cam portion 36, then the peaks 324 of the second cam surface 322 slide along the first cam surface 242 until the peaks 324 slide over the peaks 244 of the first cam surfaces 242. The manual opening angle corresponds to the angle including the first sub-cam portion 26 sliding relative to the second sub-cam portion 36 and the peaks 324 sliding along the first cam surfaces 242. This can increase the manual opening angle of the mobile phone 100.

It should be understood that the cam portions of follower 20 and the cam 30 may have other shapes. The shape of the cam portion may be changed according to the opening angle of the cover. The washer 60 may be soldered to the shaft 10. The head portion 12 may be integrally formed with the main shaft 10.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A hinge assembly for connecting a cover and a main body of a foldable electronic device, comprising:
a shaft;
a follower disposed on the shaft, one end of the follower having a first cam surface, the first cam surface forming a first sub-cam portion;
a cam positioned on the shaft and adjacent to the follower, the cam having a second cam surface, the second cam surface engaging with the first cam surface, the second cam surface forming a second sub-cam portion, the first sub-cam portion engaging with the second sub-cam portion; and
a resilient member placed around the shaft forcing the first cam surface against the second cam surface;
wherein after the first sub-cam portion slides and rotates relative to the second sub-cam portion, the first cam surface slides and rotates relative to the second cam surface.

2. The hinge assembly of claim 1, wherein the first sub-cam portion is positioned at an inner portion of the first cam surface, the second sub-cam portion is positioned at an inner portion of the second cam surface.

3. The hinge assembly of claim 2, wherein the first cam surface defines a first groove, the follower defines a hole, the first groove communicates with an inner portion of the first cam surface and the hole.

4. The hinge assembly of claim 3, wherein the first sub-cam portion is opposite to the first groove, and the second sub-cam portion is opposite to the second groove.

5. A foldable electronic device, comprising:
a main body;
a cover rotatably mounted with the main body; and
a hinge assembly connecting the cover to the main body, the hinge assembly comprising:
a follower disposed on the shaft, one end of the follower having a first cam surface, the first cam surface forming a first sub-cam portion;
a cam positioned on the shaft and adjacent to the follower, the cam having a second cam surface, the second cam surface engaging with the first cam surface, the second cam surface forming a second sub-cam portion, the first sub-cam portion engaging with the second sub-cam portion; and
a resilient member placed around the shaft forcing the first cam surface against the second cam surface;
wherein the resilient member is positioned such that the first cam surface of the follower is forced against the second cam surface of the cam due to a force of the resilient member, and after the first sub-cam portion rotates relative to the second sub-cam portion, the first cam surface rotates relative to the second cam surface.

6. The foldable electronic device of claim 5, wherein the first sub-cam portion is positioned at an inner portion of the first cam surface, the second sub-cam portion is positioned at an inner portion of the second cam surface.

7. The foldable electronic device of claim 6, wherein the first cam surface defines a first groove, the follower defines a hole, the first groove communicates with an inner portion of the first cam surface and the hole.

8. The foldable electronic device of claim 7, wherein the first sub-cam portion is opposite to the first groove, and the second sub-cam portion is opposite to the second groove.

9. A hinge assembly for interconnecting a cover and a main body of a foldable electronic device, comprising:
a shaft;
a cam mounted on the shaft, one end of the cam having a cam portion, the cam portion forming a sub-cam portion and defining a first groove;
a follower mounted on the shaft and adjacent to the cam, one end of the follower having a latching cam portion, the latching cam portion forming a latching sub-cam portion engaging with the sub-cam portion, the second cam portion defining a second groove, the first groove receiving the latching sub-cam portion and the second groove receiving the sub-cam portion; and
a resilient member proving a force to allow the follower to rotate relative to the cam.

10. The hinge assembly of claim 9, wherein the first sub-cam portion is positioned at an inner portion of the first cam surface, the second sub-cam portion is positioned at an inner portion of the second cam surface.

11. The hinge assembly of claim 10, wherein the first sub-cam portion is opposite to the first groove, and the second sub-cam portion is opposite to the second groove.
